(19) United States
(12) Patent Application Publication
(10) Pub. No.: US 2018/0108709 A1
(43) Pub. Date: Apr. 19, 2018

(54) Organic Light Emitting Diode Device Integrated with Color Filter Electrode and Method of Manufacturing the Same

(71) Applicant: Korea Advanced Institute of Science and Technology, Daejeon (KR)

(72) Inventors: Kyung Cheol Choi, Daejeon (KR); Jun Hee Han, Daejeon (KR)

(21) Appl. No.: 15/630,114

(22) Filed: Jun. 22, 2017

(30) Foreign Application Priority Data
Oct. 14, 2016 (KR) 10-2016-0133694

(51) Int. Cl. H01L 27/32; H01L 51/52; H01L 51/56

(52) U.S. Cl. CPC H01L 27/322; H01L 51/5221; H01L 27/3248; H01L 51/5012; H01L 51/56; H01L 51/5206; H01L 51/5275

(57) ABSTRACT

Provided are an organic light emitting diode (OLED) device integrated with a color filter electrode, which is formed by inserting an intermediate layer having conductivity between a plurality of metal films, and a method of manufacturing the same. The OLED device includes: a first electrode layer configured to function as an anode electrode to provide holes; an organic emission layer disposed above the first electrode layer and configured to cause a reaction between the holes and electrons to generate light; and a color filter electrode layer disposed above the first electrode layer and the organic emission layer and configured to selectively transmit a color in each region, function as a cathode electrode due to conductivity thereof, and provide the electrons to the organic emission layer.

### CROSS-REFERENCE TO RELATED APPLICATION

This application claims priority to Korean Patent Application No. 10-2016-0133694 filed Oct. 14, 2016, the disclosure of which is hereby incorporated in its entirety by reference.

### BACKGROUND OF THE INVENTION

### Field of the Invention

The present invention relates to an organic light emitting diode (OLED) device integrated with a color filter electrode and a method of manufacturing the same, and more particularly, to an OLED device integrated with a color filter electrode, which is formed by inserting an intermediate layer having conductivity between a plurality of metal films, and a method of manufacturing the same.

### Description of Related Art

Organic light emitting diode (OLED) devices are self-emission devices that produce full-color images and have wide viewing angles, high contrast ratios, short response times, and excellent characteristics in terms of brightness, driving voltage, and response speed.

A general OLED device may include a transparent substrate, an anode, a cathode, and an organic layer disposed between the anode and the cathode. The organic layer may include a hole injection layer, a hole transport layer, an emission layer, an electron transport layer, and an electron injection layer. Holes injected from the anode move toward the emission layer through the hole transport layer, and electrons injected from the cathode move toward the emission layer through the electron transport layer. Carriers, such as the holes and the electrons, recombine in the emission layer region to produce excitons. These excitons change from an excited state to a ground state to thereby generate light.

In this regard, as illustrated in FIG. 1, a top-emission type OLED device capable of reproducing red, green, and blue colors is manufactured by using a method of attaching a substrate on which a color filter is formed and a substrate on which a white OLED is formed.

In this case, the color filter is formed on the substrate by using various methods, such as dyeing, printing, electrophoretic deposition, or photolithography. However, much cost and time are required for forming the color filter because separate processes for red, green, and blue colors are performed.

In addition, when the color filter is attached to the white OLED, a position of a transistor serving as a driving unit of the white OLED and a position of an electrode part need to be aligned with a position of the color filter. At this time, a highly sophisticated process needs to be performed in the alignment process.

This method makes a device manufacturing process very complicated and increases time and manufacturing cost.

### PRIOR ART DOCUMENT

### Patent Document

(Patent Document 1) Korean Patent Application Publication No. 10-2003-0017748

(Patent Document 2) Korean Patent Application Publication No. 10-2016-0048534

(Patent Document 3) Korean Patent Application Publication No. 10-2011-0069413

(Patent Document 4) Korean Patent Application Publication No. 10-2002-0016112

(Patent Document 5) Korean Patent Application Publication No. 10-2002-0092438

### SUMMARY OF THE INVENTION

One or more embodiments of the present invention include an organic light emitting diode (OLED) device integrated with a color filter electrode layer, which has an electrode or line function as well as a filtering function by forming a stack structure including an intermediate layer having conductivity and capable of electrically connecting metal films.

According to one or more embodiments of the present invention, an OLED device integrated with a color filter electrode includes: a first electrode layer configured to function as an anode electrode to provide holes; an organic emission layer disposed above the first electrode layer and configured to cause a reaction between the holes and electrons to generate light; and a color filter electrode layer disposed above the first electrode layer and the organic emission layer and configured to selectively transmit a color in each region, function as a cathode electrode due to conductivity thereof, and provide the electrons to the organic emission layer.

The OLED device may further include an electronic element layer disposed below the first electrode layer and configured to receive a driving signal from an external driver and control the first electrode layer.

The color filter electrode layer may include: a first metal film disposed above the organic emission layer; an intermediate layer disposed above the first metal film and having conductivity; and a second metal film disposed above the intermediate layer.

The OLED device may further include a first outer layer disposed between the first metal film and the organic emission layer and having conductivity.

When a refractive index of the intermediate layer is in a range of 1.0 to 3.0, the intermediate layer may include: a blue color filter electrode layer having a thickness of 1 nm to 230 nm; a green color filter electrode layer having a thickness of 30 nm to 270 nm; and a red color filter electrode layer having a thickness of 40 nm to 320 nm.

The OLED device may further include a second outer layer disposed above the second metal film and having conductivity.

According to one or more embodiments of the present invention, an OLED device integrated with a color filter electrode includes: a color filter electrode layer configured to selectively transmit a color in each region and function as a cathode electrode to provide electrons; an organic emission layer disposed above the color filter electrode layer and configured to cause a reaction between the electrons and holes to generate light; and a first electrode layer disposed above the organic emission layer and configured to function as an anode electrode to provide the holes.

The OLED device may further include an electronic element layer disposed below the color filter electrode layer and configured to receive a driving signal from an external driver and control the color filter electrode layer.

The color filter electrode layer may include: a first metal film disposed below the organic emission layer; an intermediate layer disposed below the first metal film and having conductivity; and a second metal film disposed below the intermediate layer.

The intermediate layer may include one or more materials selected from aluminum oxide, aluminum nitride, tungsten oxide (WO3), silicon oxide (SiO2), silicon nitride, silicon oxynitride, magnesium oxide (MgO), magnesium fluoride, titanium oxide, titanium nitride, hafnium oxide, hafnium nitride, zirconium oxide, and zirconium nitride, and a difference of work functions between the intermediate layer and the first and second metal films may be in a range of 0 eV to 2 eV, so that when power is supplied between the first metal film and the second metal film, electrons move from the first metal film and the second metal film to the intermediate layer and move from the intermediate layer to the first metal film and the second metal film, whereby the intermediate layer has conductivity.

The intermediate layer may include transparent conductive oxide (TCO) or a conductive organic compound.

When a refractive index of the intermediate layer is in a range of 1.0 to 3.0, the intermediate layer may include: a blue color filter electrode layer having a thickness of 15 nm to 170 nm; a green color filter electrode layer having a thickness of 30 nm to 220 nm; and a red color filter electrode layer having a thickness of 40 nm to 270 nm.

According to one or more embodiments of the present invention, a method of manufacturing an OLED device integrated with a color filter electrode includes: (A) forming a first electrode layer, the first electrode layer being configured to function as an anode electrode to provide holes to an organic emission layer; (B) forming the organic emission layer above the first electrode layer, the organic emission layer being configured to cause a reaction between the holes and electrons to generate light; and (C) forming a color filter electrode layer above the first electrode layer and the organic emission layer, the color filter electrode layer being configured to selectively transmit a color in each region and function as a cathode electrode to provide the electrons to the organic emission layer.

The method may further include, before (A), (D) forming an electronic element layer below the first electrode layer, the electronic element layer being configured to receive a driving signal from an external driver above a substrate.

(C) may include: (C-1) forming a first metal film above the organic emission layer; (C-2) forming an intermediate layer having conductivity above the first metal film; and (C-3) forming a second metal film above the intermediate layer.

The method may further include, before (C-1) of forming the first metal film above the organic emission layer, (C-4) forming a first outer layer having conductivity.

The method may further include (C-5) forming a second outer layer having conductivity above the second metal film.

According to one or more embodiments of the present invention, a method of manufacturing an OLED device integrated with a color filter electrode includes: (A) forming a color filter electrode layer, the color filter electrode layer being configured to selectively transmit a color in each region and function as a cathode electrode to provide electrons to an organic emission layer; (B) forming the organic emission layer above the color filter electrode layer, the organic emission layer being configured to receive holes from a first electrode layer and generate light according to a driving signal of an electronic element layer; and (C) forming the first electrode layer above the organic emission layer, the first electrode layer being configured to provide the holes to the organic emission layer.

The method may further include, before (A), (D) forming the electronic element layer below the color filter electrode layer, the electronic element layer being configured to receive a driving signal from an external driver above a substrate.

(A) may include: (A-1) forming a second metal film; (A-2) forming an intermediate layer having conductivity above the second metal film; and (A-3) forming a first metal film above the intermediate layer.

The method may further include, before (A-1) of forming the second metal film above the organic emission layer, (A-4) forming a second outer layer having conductivity.

The method may further include (A-5) forming a first outer layer having conductivity above the first metal film.

According to the embodiments of the present invention, it is possible to reduce the manufacturing process and simplify the manufacturing process, thereby reducing the manufacturing cost.

In particular, the OLED device includes the color filter electrode layer in which the color filter and the electrode are integrated, and a thermal deposition process used to manufacture the OLED is employed in the method of manufacturing the OLED device. Thus, the color filter electrode layer is just subsequently manufactured at the same time as the manufacturing of the OLED device, without additional processes.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a diagram for describing a process of manufacturing an organic light-emitting diode (OLED) device according to the related art;

FIG. 2A is a configuration diagram of an OLED device integrated with a color filter electrode, according to a first embodiment of the present invention; FIG. 2B is a detailed configuration diagram of a color filter electrode layer of FIG. 2A;

FIG. 3 is a graph showing a transmittance of a red color filter electrode layer of FIG. 2B;

FIG. 4 is a graph showing a transmittance of a green color filter electrode layer of FIG. 2B;

FIG. 5 is a graph showing a transmittance of a blue color filter electrode layer of FIG. 2B;

FIG. 6 is a graph showing a sheet resistance of a color filter electrode layer of FIG. 2B according to a change in a thickness of a first metal film;

FIG. 7 is a graph showing a transmittance of a color filter electrode layer of FIG. 2B according to a change in a thickness of a first metal film;

FIG. 8 is a configuration diagram of an OLED device integrated with a color filter electrode, according to a second embodiment of the present invention;

FIG. 9 is another configuration diagram of the color filter electrode layers of FIGS. 2 and 8;

FIG. 10 is a graph showing a transmittance of a red color filter electrode layer of FIG. 9;

FIG. 11 is a graph showing a transmittance of a green color filter electrode layer of FIG. 9;

FIG. 12 is a graph showing a transmittance of a blue color filter electrode layer of FIG. 9;

FIG. 13 is a flowchart of a method of manufacturing an OLED device integrated with a color filter electrode, according to a first embodiment of the present invention; and

FIG. 14 is a flowchart of a method of manufacturing an OLED device integrated with a color filter electrode, according to a second embodiment of the present invention.

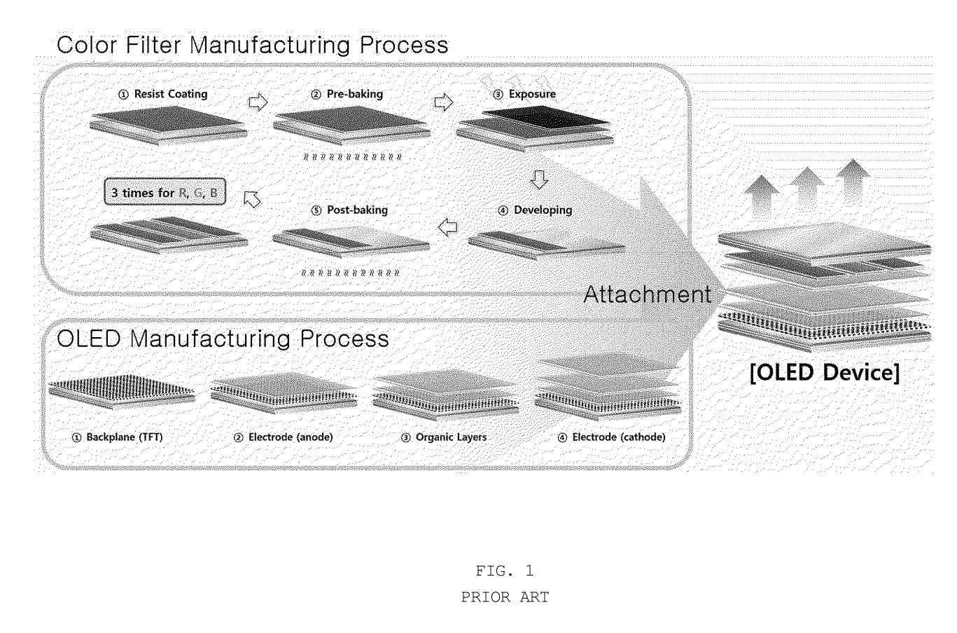

### DESCRIPTION OF THE INVENTION

Hereinafter, specific embodiments of the present invention will be described in detail with reference to the accompanying drawings.

While describing the present invention, detailed descriptions about related well-known functions or configurations that may diminish the clarity of the points of the present invention are omitted.

Also, it will be understood that although the terms “first”, “second”, etc. may be used herein to describe various components, these components should not be limited by these terms. These components are only used to distinguish one component from another.

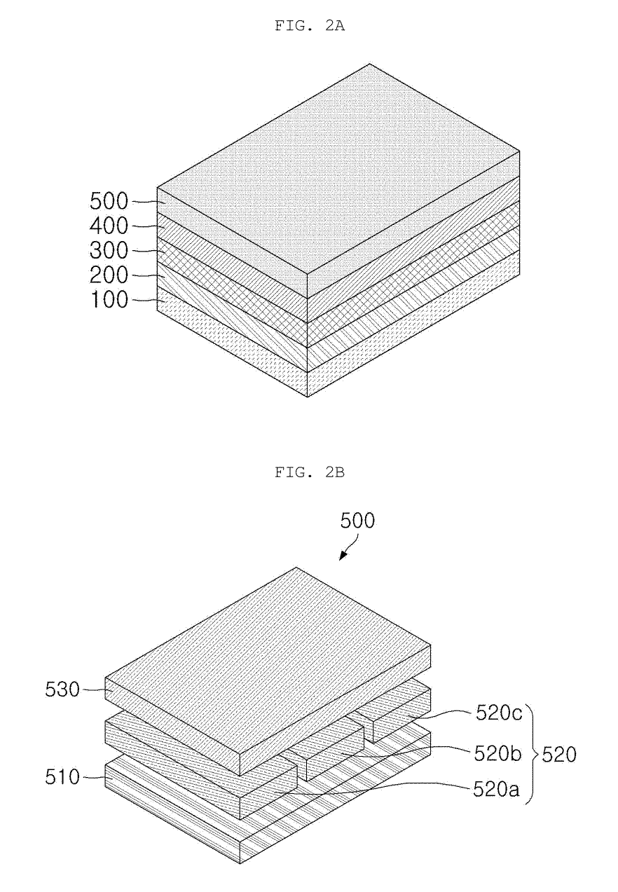

FIG. 2A is a configuration diagram of an organic light emitting diode (OLED) device integrated with a color filter electrode, according to a first embodiment of the present invention, and FIG. 2B is a detailed configuration diagram of a color filter electrode layer of FIG. 2A.

Referring to FIG. 2A, the OLED device integrated with the color filter electrode, according to the first embodiment of the present invention, includes a substrate 100, an electronic element layer 200, a first electrode layer 300, an organic emission layer 400, and a color filter electrode layer 500.

The color filter electrode layer 500 may include a first metal film 510, an intermediate layer 520, and a second metal film 530. The intermediate layer 520 may include a red color filter electrode layer 520a configured to transmit a wavelength of a red region, a green color filter electrode layer 520b configured to transmit a wavelength of a green region, and a blue color filter electrode layer 520c configured to transmit a wavelength of a blue region.

The substrate 100 may be a flexible substrate. The substrate 100 may include a plastic material having excellent heat resistance and durability, such as polyimide (PI), polyethylene terephthalate (PET), polyethylene naphthalate (PEN), polycarbonate (PC), polyarylate (PAR), polyetherimide (PEI), and polyethersulphone (PES). However, the present invention is not limited thereto. Various flexible materials, such as a metal foil or a thin glass, may be used.

The substrate 100 may be a rigid substrate. In this case, the substrate 100 may include a glass material containing SiO2 as a main component.

The OLED device according to the first embodiment is a top-emission type OLED device in which an image is realized in a direction opposite to the substrate 100. The substrate 100 does not necessarily need to be made of a transparent material. In this case, the substrate 100 may be made of a metal.

When the substrate 100 is made of a metal, the substrate 100 may include one or more selected from the group consisting of carbon, iron, chromium, manganese, nickel, titanium, molybdenum, and stainless steel (SUS), but is not limited thereto.

The electronic element layer 200 may include a driving thin film transistor (TFT) configured to drive the organic emission layer 400, a switching TFT, a capacitor, and lines connected to the TFTs or the capacitor.

Electronic elements of the electronic element layer 200 are electrically connected to the lines and configured to receive a driving signal from an external driver and drive the organic emission layer 400.

The first electrode layer 300 is an anode electrode. The first electrode layer 300 is connected to a drain electrode of the driving TFT and configured to receive positive power from the drain electrode and provide holes to the organic emission layer 400.

The first electrode layer 300 includes indium tin oxide (ITO), indium zinc oxide (IZO), or indium tin zinc oxide (ITZO) and is connected to the drain electrode.

A low-molecular-weight organic film or a high-molecular-weight organic film may be used as the organic emission layer 400. When the low-molecular-weight organic film is used, the organic emission layer 400 may have a single-layered structure or a multi-layered stack structure of a hole injection layer (HIL), a hole transport layer (HTL), an emission layer (EML), an electron transport layer (ETL), and an electron injection layer (EIL). Various organic materials may be used in the organic emission layer 400. Examples of such organic materials may include copper phthalocyanine (CuPc), N,N′-di(naphthalene-1-yl)-N,N′-diphenylbenzidine (NPB), and tris-8-hydroxyquinoline aluminum (Alq3).

When the high-molecular-weight organic film is used, the organic emission layer 400 may have a structure including a hole transport layer (HTL) and an emission layer (EML). In this case, poly(3,4-ethylenedioxythiophene) (PEDOT) may be used as the hole transport layer, and high-molecular-weight organic materials such as a poly-phenylenevinylene-based material and a polyfluorene-based material may be used as the emission layer. For reference, in the emission layer, sub-pixels configured to emit red light, green light, and blue light may constitute one unit pixel. Alternatively, instead of forming a separate emission material at each sub-pixel, the emission layer may be commonly formed on the entire surfaces of the sub-pixels, regardless of positions of the sub-pixels. In this case, the emission layer may be formed by vertically stacking or mixing layers including emission materials emitting red light, green light, and blue light. Any combination of other colors may also be applied as long as the combination can emit white light.

Since the color filter electrode layer 500 includes the first metal film 510, the intermediate layer 520 disposed above the first metal film 510 and having conductivity, and the second metal film 530 disposed above the intermediate layer 520, the color filter electrode layer 500 functions as a color filter. Also, since the color filter electrode layer 500 has conductivity, the color filter electrode layer 500 functions as a cathode electrode to provide electrons to the organic emission layer 400.

The first metal film 510 of the color filter electrode layer 500 may be stacked above the organic emission layer 400 and may include a metal having excellent flexibility and conductivity, such as Ag, Al, Au, Cr, Ni, Pt, Ca, Ta, Cu, and Mo, or any alloy thereof. A thickness of the first metal film 510 may be in a range of 7 nm to 50 nm.

The intermediate layer 520 transmits different colors according to a thickness thereof. The intermediate layer 520 may include the red color filter electrode layer 520a configured to transmit the wavelength of the red region, the green color filter electrode layer 520b configured to transmit the wavelength of the green region, and the blue color filter electrode layer 520c configured to transmit the wavelength of the blue region.

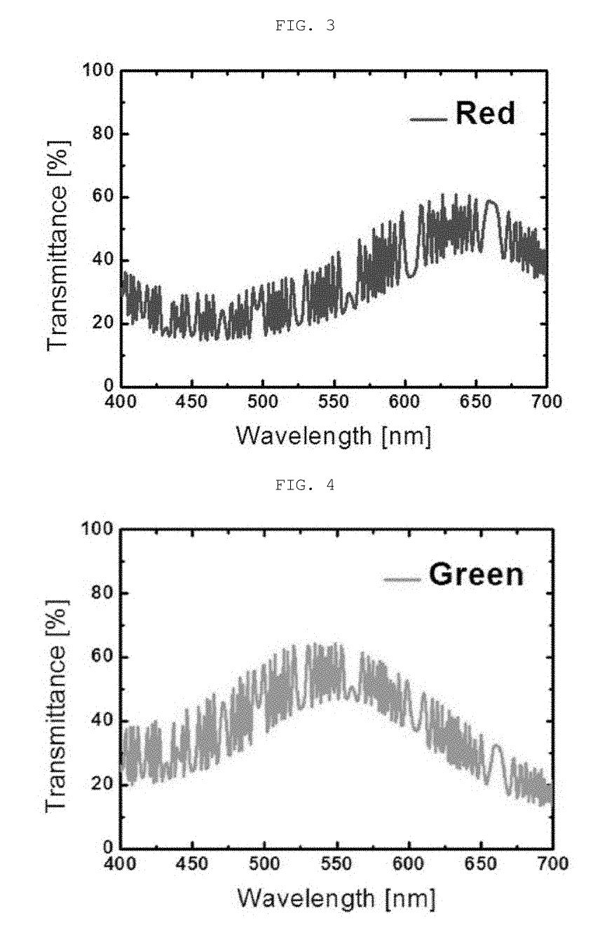

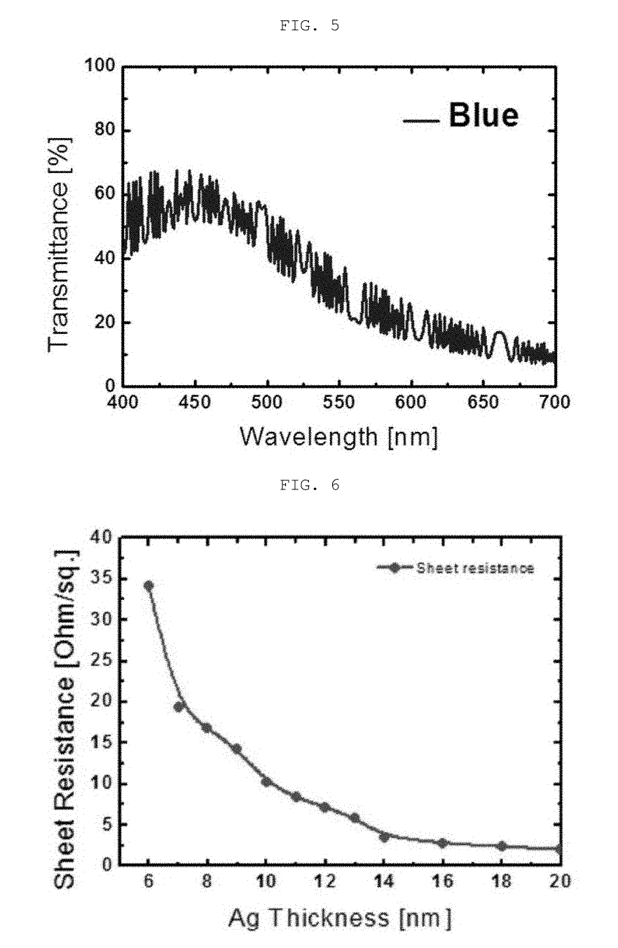

When the intermediate layer 520 is made of WO₃ and has a thickness greater than 80 nm and equal to or less than 100 nm, the intermediate layer 520 transmits a red-based color best as illustrated in FIG. 3, and thus, the intermediate layer 520 is used as the red color filter electrode layer 520a. When the intermediate layer 520 has a thickness greater than 60 nm and equal to or less than 80 nm, the intermediate layer 520 transmits a green-based color best as illustrated in FIG. 4, and thus, the intermediate layer 520 is used as the green color filter electrode layer 520b. When the intermediate layer 520 has a thickness equal to or greater than 35 nm and equal to or less than 60 nm, the intermediate layer 520 transmits a blue-based color best as illustrated in FIG. 5, and thus, the intermediate layer 520 is used as the blue color filter electrode layer 520c.

The intermediate layer 520 is stacked above the first metal film 510 and includes, in addition to WO₃, one or more materials selected from aluminum oxide, aluminum nitride, silicon oxide (SiO2), silicon nitride, silicon oxynitride, magnesium oxide (MgO), magnesium fluoride, titanium oxide, titanium nitride, hafnium oxide, hafnium nitride, zirconium oxide, and zirconium nitride, such as Al₂O₃, ZnO, ZrO_{2,} TiO_{2,} MgO, ZnS, Y₂O₃, HfO₂, SiO₂, SiNₓ, and AlN.

When these materials are used, the intermediate layer 520 has conductivity when a difference of work functions between the first metal film 510 and the second metal film 530 is in a range of 0 eV to 2 eV.

In a case where the material of the intermediate layer 520 inserted between the first metal film 510 and the second metal film 530 is a material that does not greatly exhibit conductivity just like the dielectric presented above, if a dielectric having a work function similar to the work functions of the first metal film 510 and the second metal film 530 is used (for example, if a difference of work functions is in a range of 0 eV to 2 eV), a difference of work functions when the first metal film 510 and the second metal film 530 contact the intermediate layer 520 is not great. Thus, electrons easily move from the metal to the dielectric and from the dielectric to the metal, and the intermediate layer 520 has conductivity accordingly.

In addition, the intermediate layer 520 may include transparent conductive oxide (TCO) such as ITO, IGZO, or IZO.

Furthermore, the intermediate layer 520 may include a conductive organic compound such as NPB, Alq3, TPBi, or PEDOT:PSS.

The second metal film 530 may be stacked above the intermediate layer 520 and may include a metal having excellent flexibility and conductivity, such as Ag, Al, Au, Cr, Ni, Pt, Ca, Ta, Cu, and Mo, or any alloy thereof.

The color filter electrode layer 500 having the above-described structure is used as the red color filter electrode layer, the green color filter electrode layer, and the blue color filter electrode layer by transmitting different colors according to a change in the thickness of the intermediate layer 520. Since the intermediate layer 520 has conductivity, the color filter electrode layer 500 has conductivity as a whole and is used as a cathode electrode.

FIGS. 3 to 5 illustrate transmittances when WO₃ is used as the intermediate layer 520 and the thickness of the intermediate layer 520 is changed as shown in Table 1, in a state in which Ag is used as the first metal film 510, the thickness of the first metal film 510 is fixed to 20 nm, Ag is used as the second metal film 530, and the thickness of the second metal film 530 is fixed to 10 nm.

TABLE 1

| | First metal | Intermediate | Second metal | Peak |
|---|---|---|---|---|
| Color | film | layer | film | wavelength (x) |
| Red | 20 | 93 | 10 | 650 nm |
| Green | 20 | 70 | 10 | 550 nm |
| Blue | 20 | 45 | 10 | 450 nm |

Table 1 above shows a peak wavelength (x) of each case.

In this regard, Table 2 below shows a peak wavelength range according to a thickness range of the intermediate layer 520.

TABLE 2

| | | Intermediate | Second | |
|---|---|---|---|---|
| | First metal | layer | metal | Peak |
| Color | film | (thickness d) | film | wavelength (x) |
| Red | 20 | 80 < d ≤ 100 | 10 | 600 nm < x |
| Green | 20 | 60 < d ≤ 80 | 10 | 500 nm < x < 600 nm |
| Blue | 20 | 35 ≤ d ≤ 60 | 10 | x < 500 nm |

Since the thickness of the intermediate layer 520 is greatly affected by a refractive index of a material, thickness (d) conditions for more various materials may be determined by taking into account the refractive index. These thickness conditions are shown in Table 3 below. The thickness range of the intermediate layer 520 is actually available when a refractive index is in a range of 1.4 to 2.7.

TABLE 3

| Refractive | Blue | Green | Red |
|---|---|---|---|
| index (x) | (400 nm-500 nm) | 500 nm-600 nm) | (600 nm-700 nm) |
| 1.0 ≤ x < 1.1 | 130 nm ≤ d ≤ 170 nm | 170 nm < d ≤ 220 nm | 220 nm < d ≤ 270 nm |
| 1.1 ≤ x < 1.2 | 120 nm ≤ d ≤ 150 nm | 150 nm < d ≤ 200 nm | 200 nm < d ≤ 240 nm |
| 1.2 ≤ x < 1.3 | 100 nm ≤ d ≤ 130 nm | 130 nm < d ≤ 170 nm | 170 nm < d ≤ 210 nm |
| 1.3 ≤ x < 1.4 | 80 nm ≤ d ≤ 120 nm | 120 nm < d ≤ 150 nm | 150 nm < d ≤ 190 nm |
| 1.4 ≤ x < 1.5 | 70 nm ≤ d ≤ 110 nm | 110 nm < d ≤ 140 nm | 140 nm < d ≤ 170 nm |
| 1.5 ≤ x < 1.6 | 60 nm ≤ d ≤ 90 nm | 90 nm < d ≤ 120 nm | 120 nm < d ≤ 160 nm |
| 1.6 ≤ x < 1.7 | 60 nm ≤ d ≤ 80 nm | 80 nm < d ≤ 110 nm | 110 nm < d ≤ 150 nm |
| 1.7 ≤ x < 1.8 | 50 nm ≤ d ≤ 75 nm | 75 nm < d ≤ 105 nm | 105 nm < d ≤ 130 nm |
| 1.8 ≤ x < 1.9 | 45 nm ≤ d ≤ 70 nm | 70 nm < d ≤ 95 nm | 95 nm < d ≤ 120 nm |
| 1.9 ≤ x < 2.0 | 40 nm ≤ d ≤ 65 nm | 65 nm < d ≤ 90 nm | 90 nm < d ≤ 110 nm |
| 2.0 ≤ x < 2.1 | 35 nm ≤ d ≤ 60 nm | 60 nm < d ≤ 80 nm | 80 nm < d ≤ 100 nm |
| 2.1 ≤ x < 2.2 | 30 nm ≤ d ≤ 55 nm | 55 nm < d ≤ 75 nm | 75 nm < d ≤ 100 nm |
| 2.2 ≤ x < 2.3 | 25 nm ≤ d ≤ 50 nm | 50 nm < d ≤ 70 nm | 70 nm < d ≤ 95 nm |
| 2.3 ≤ x < 2.4 | 25 nm ≤ d ≤ 45 nm | 45 nm < d ≤ 65 nm | 65 nm < d ≤ 90 nm |
| 2.4 ≤ x < 2.5 | 20 nm ≤ d ≤ 40 nm | 40 nm < d ≤ 60 nm | 60 nm < d ≤ 85 nm |
| 2.5 ≤ x < 2.6 | 20 nm ≤ d ≤ 40 nm | 40 nm < d ≤ 55 nm | 55 nm < d ≤ 80 nm |
| 2.6 ≤ x < 2.7 | 20 nm ≤ d ≤ 35 nm | 35 nm < d ≤ 50 nm | 50 nm < d ≤ 75 nm |
| 2.7 ≤ x < 2.8 | 20 nm ≤ d ≤ 35 nm | 35 nm < d ≤ 50 nm | 50 nm < d ≤ 70 nm |
| 2.8 ≤ x < 2.9 | 15 nm ≤ d ≤ 30 nm | 30 nm < d ≤ 45 nm | 45 nm < d ≤ 65 nm |
| 2.9 ≤ x < 3.0 | 15 nm ≤ d ≤ 30 nm | 30 nm < d ≤ 40 nm | 40 nm < d ≤ 60 nm |

FIG. 6 illustrates a sheet resistance according to a change in the thickness of the first metal film 510. It can be seen from FIG. 6 that as the thickness of the first metal film 510 increases, the sheet resistance is reduced.

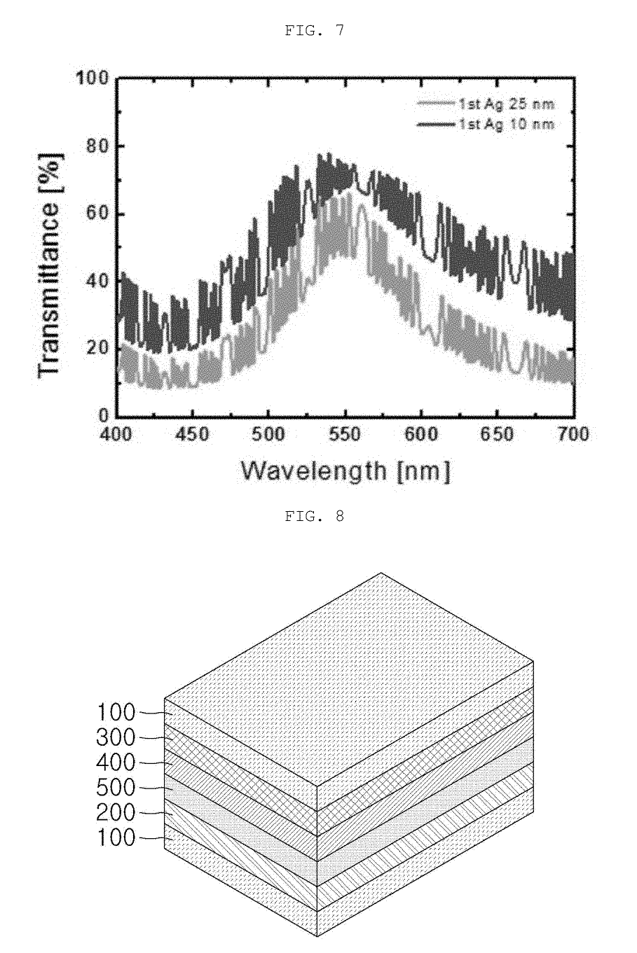

FIG. 7 illustrates a transmittance according to a change in the thickness of the first metal film 510. It can be seen from FIG. 7 that as the thickness of the first metal film 510 increases, the transmittance is reduced and a full width half maximum (FWHM) is improved.

Since the sheet resistance, the transmittance, and the FWHM are associated with one another, an appropriate tradeoff is required for obtaining optimal performance.

FIG. 8 is a configuration diagram of an OLED device integrated with a color filter electrode, according to a second embodiment of the present invention.

Referring to FIG. 8, the OLED device integrated with the color filter electrode, according to the second embodiment of the present invention, includes a substrate 100, an electronic element layer 200, a first electrode layer 300, an organic emission layer 400, and a color filter electrode layer 500. These elements are substantially identical to those of the OLED device according to the first embodiment. However, the OLED device according to the second embodiment differs from the OLED device according to the first embodiment in terms of stacked order. Specifically, in the OLED device according to the second embodiment, the substrate 100, the electronic element layer 200, the color filter electrode layer 500, the organic emission layer 400, the first electrode layer 300, and the substrate 100 are stacked in this order. Thus, the OLED device according to the second embodiment is a bottom-emission type OLED device in which an image is realized toward the lower substrate 100.

In the case of such a bottom-emission type OLED device, the lower substrate 100 needs to be made of a transparent material.

Structures and features other than those described above are substantially identical to those of the first embodiment, and detailed descriptions thereof will be omitted.

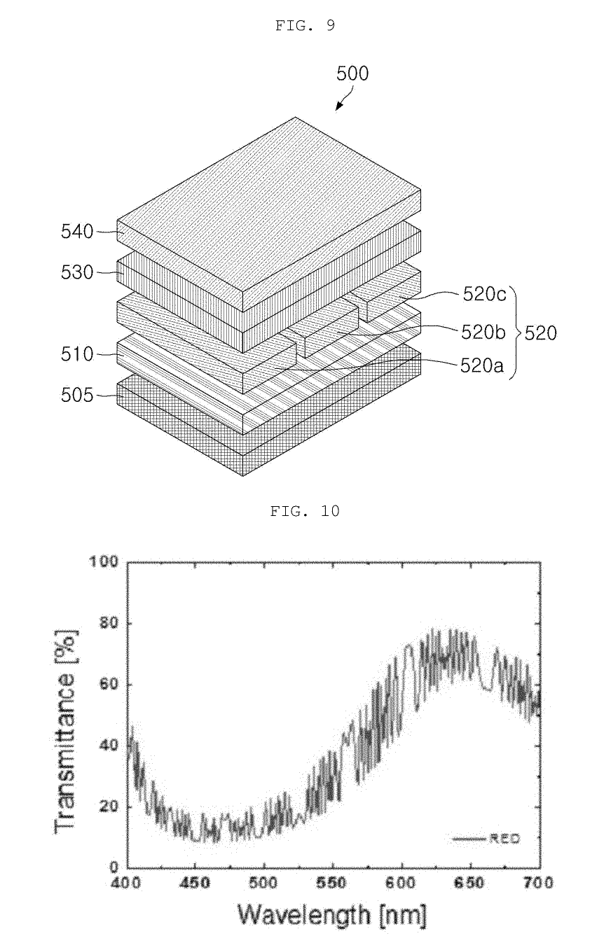

FIG. 9 is another configuration diagram of the color filter electrode layers of FIGS. 2 and 8.

Referring to FIG. 9, another configuration of the color filter electrode layers of FIGS. 2 and 8 includes a first outer layer 505, a first metal film 510, an intermediate layer 520, a second metal film 530, and a second outer layer 540.

The first outer layer 505 serves to adjust an FWHM value rather than transmit different colors according to a thickness thereof.

The first outer layer 505 does not have a specific thickness range according to RGB, and the thickness of the first outer layer 505 is determined in a range of 1 nm to 150 nm according to a desired FWHM value.

The first outer layer 505 includes, in addition to WO₃, one or more materials selected from aluminum oxide, aluminum nitride, silicon oxide (SiO₂), silicon nitride, silicon oxynitride, magnesium oxide (MgO), magnesium fluoride, titanium oxide, titanium nitride, hafnium oxide, hafnium nitride, zirconium oxide, and zirconium nitride, such as Al₂O₃, ZnO, ZrO₂, TiO₂, MgO, ZnS, Y₂O₃, HfO₂, SiO₂, SiNₓ and AlN.

When these materials are used, the first outer layer 505 has conductivity when a difference of work functions between the first outer layer 505 and the first metal film 510 is in a range of 0 eV to 2 eV.

In a case where the material of the first outer layer 505 adjacent to the first metal film 510 is a material that does not greatly exhibit conductivity just like the dielectric presented above, if a dielectric having a work function similar to the work function of the first metal film 510 is used (for example, if a difference of the work functions is in a range of 0 eV to 2 eV), a difference of work functions when the first metal film 510 contacts the first outer layer 505 is not great. Thus, electrons easily move from the metal to the dielectric and from the dielectric to the metal, and the first outer layer 505 has conductivity accordingly.

In addition, the first outer layer 505 may include TCO such as ITO, IGZO, or IZO.

Furthermore, the first outer layer 505 may include a conductive organic compound such as NPB, Alq3, TPBi, or PEDOT:PSS.

The thickness of the first outer layer 505 changes according to the thickness of the intermediate layer 520 and changes according to a refractive index of a material used therein.

The first metal film 510 may be stacked above the first outer layer 505 and may include a metal having excellent flexibility and conductivity, such as Ag, Al, Au, Cr, Ni, Pt, Ca, Ta, Cu, and Mo, or any alloy thereof. The thickness of the first metal film 510 may be in a range of 7 nm to 50 nm.

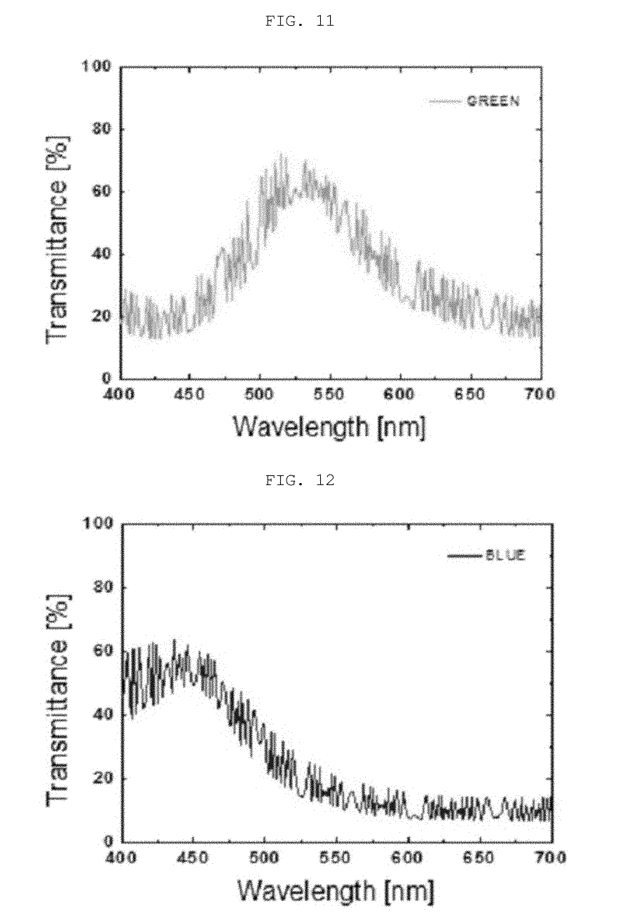

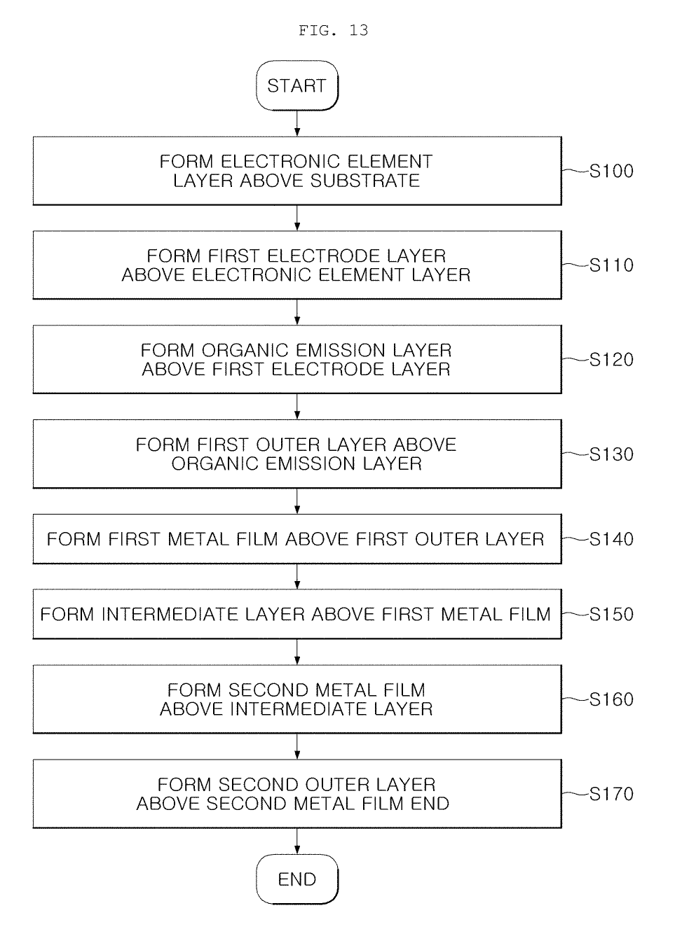

The intermediate layer 520 transmits different colors according to the thickness thereof. In a case where the material of the intermediate layer 520 is WO₃, when the intermediate layer 520 has a thickness greater than 105 nm and equal to or less than 130 nm, the intermediate layer 520 transmits a red-based color best as illustrated in FIG. 10, and thus, the intermediate layer 520 is used as a red color filter electrode layer 520a. When the intermediate layer 520 has a thickness greater than 68 nm and equal to or less than 100 nm, the intermediate layer 520 transmits a green-based color best as illustrated in FIG. 11, and thus, the intermediate layer 520 is used as a green color filter electrode layer 520b. When the intermediate layer 520 has a thickness greater than 40 nm and equal to or less than 65 nm, the intermediate layer 520 transmits a blue-based color best as illustrated in FIG. 12, and thus, the intermediate layer 520 is used as a blue color filter electrode layer 520c.

The intermediate layer 520 is stacked above the first metal film 510 and includes, in addition to WO₃, one or more materials selected from aluminum oxide, aluminum nitride, silicon oxide (SiO₂), silicon nitride, silicon oxynitride, magnesium oxide (MgO), magnesium fluoride, titanium oxide, titanium nitride, hafnium oxide, hafnium nitride, zirconium oxide, and zirconium nitride, such as Al₂O₃, ZnO, ZrO₂, TiO₂, MgO, ZnS, Y₂O₃, HfO₂, SiO₂, SiNₓ, and AlN.

When these materials are used, the intermediate layer 520 has conductivity when a difference of work functions between the first metal film 510 and the second metal film 530 is in a range of 0 eV and 2 eV.

In a case where the material of the intermediate layer 520 inserted between the first metal film 510 and the second metal film 530 is a material that does not greatly exhibit conductivity just like the dielectric presented above, if a dielectric having a work function similar to the work functions of the first metal film 510 and the second metal film 530 is used (for example, if a difference of work functions is in a range of 0 eV and 2 eV), a difference of work functions when the first metal film 510 and the second metal film 530 contact the intermediate layer 520 is not great. Thus, electrons easily move from the metal to the dielectric and from the dielectric to the metal, and the intermediate layer 520 has conductivity accordingly.

In addition, the intermediate layer 520 may include TCO such as ITO, IGZO, or IZO.

Furthermore, the intermediate layer 520 may include a conductive organic compound such as NPB, Alq3, TPBi, or PEDOT:PSS.

In a case where the refractive index is in a range of 1 to 3, the thickness of the intermediate layer 520 is in a range of 1 nm to 230 nm when the intermediate layer 520 is used as the blue color filter electrode layer 520c, the thickness of the intermediate layer 520 is in a range of 30 nm to 270 nm when the intermediate layer 520 is used as the green color filter electrode layer 520b, and the thickness of the intermediate layer 520 is in a range of 40 nm to 320 nm when the intermediate layer 520 is used as the red color filter electrode layer 520a.

The thickness of the intermediate layer 520 is changed according to the refractive index and is determined within the range presented above for each color.

The second metal film 530 may be stacked above the intermediate layer 520 and may include a metal having excellent flexibility and conductivity, such as Ag, Al, Au, Cr, Ni, Pt, Ca, Ta, Cu, and Mo, or any alloy thereof.

The second outer layer 540 serves to adjust an FWHM value rather than transmit different colors according to the thickness thereof.

The second outer layer 540 does not have a specific thickness range according to RGB, and the thickness of the second outer layer 540 is determined in a range of 1 nm to 150 nm according to a desired FWHM value.

The second outer layer 540 is stacked above the second metal film 530 and includes, in addition to WO₃, one or more materials selected from aluminum oxide, aluminum nitride, silicon oxide (SiO₂), silicon nitride, silicon oxynitride, magnesium oxide (MgO), magnesium fluoride, titanium oxide, titanium nitride, hafnium oxide, hafnium nitride, zirconium oxide, and zirconium nitride, such as Al₂O₃, ZnO, ZrO₂, TiO₂, MgO, ZnS, Y₂O₃, HfO₂, SiO₂, SiNₓ, and AlN.

When these materials are used, the second outer layer 540 has conductivity when a difference of work functions between the second outer layer 540 and the second metal film 530 is in a range of 0 eV and 2 eV.

In a case where the material of the second outer layer 540 adjacent to the second metal film 530 is a material that does not greatly exhibit conductivity just like the dielectric presented above, if a dielectric having a work function similar to the work function of the second metal film 530 is used (for example, if a difference of work functions is in a range of 0 eV to 2 eV), a difference of work functions when the second metal film 530 contacts the second outer layer 540 is not great. Thus, electrons easily move from the metal to the dielectric and from the dielectric to the metal, and the second outer layer 540 has conductivity accordingly.

In addition, the second outer layer 540 may include TCO such as ITO, IGZO, or IZO.

Furthermore, the second outer layer 540 may include a conductive organic compound such as NPB, Alq3, TPBi, or PEDOT:PSS.

The thickness of the second outer layer 540 changes according to the thickness of the intermediate layer and changes according to a refractive index of a material used therein.

The color filter electrode layer having the above-described structure may transmit different colors according to a change in the thicknesses of the first outer layer 505, the intermediate layer 520, and the second outer layer 540. Since the first outer layer 505, the intermediate layer 520, and the second outer layer 540 have conductivity, the color filter electrode layer has conductivity as a whole and thus may be used as a line or an electrode.

FIGS. 10 to 12 illustrate transmittances when WO₃ was used as the first outer layer 505, the thickness of the first outer layer 505 was changed as shown in Table 4 below, WO₃ was used as the intermediate layer 520, the thickness of the intermediate layer 520 was changed as shown in Table 4 below, WO₃ was used as the second outer layer 540, and the thickness of the second outer layer 540 was changed as shown in Table 4 below, in a state in which Ag was used as the first metal film 510, the thickness of the first metal film 510 was fixed to 20 nm, Ag was used as the second metal film 530, and the thickness of the second metal film 530 was fixed to 10 nm.

TABLE 4

| | First | First | Interme- | Second | Second | Peak |
|---|---|---|---|---|---|---|
| | outer | metal | diate | metal | outer | wavelength |
| Color | layer | film | layer | film | layer | (x) |
| Red | 72 | 20 | 115 | 10 | 84 | 650 nm |
| Green | 87 | 20 | 84 | 10 | 92 | 550 nm |
| Blue | 100 | 20 | 46 | 10 | 100 | 450 nm |

Table 4 above shows a peak wavelength (x) of each case. In this regard, Table 5 below shows a peak wavelength range according to the thickness range of the intermediate layer 520.

TABLE 5

| | First | First | Interme- | Second | Second | Peak |
|---|---|---|---|---|---|---|
| | outer | metal | diate | metal | outer | wavelength |
| Color | layer | film | layer | film | layer | (x) |
| Red | 72 | 20 | 115 | 10 | 84 | 650 nm |
| Green | 87 | 20 | 84 | 10 | 92 | 550 nm |
| Blue | 100 | 20 | 46 | 10 | 100 | 450 nm |

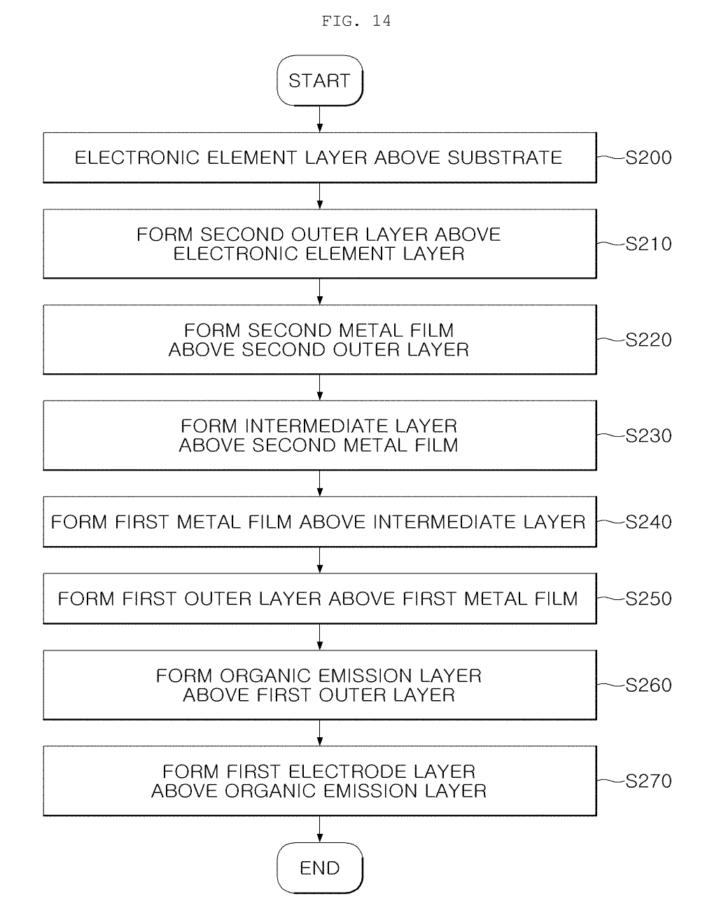

FIG. 13 is a flowchart of a method of manufacturing an OLED device integrated with a color filter electrode, according to a first embodiment of the present invention.

Referring to FIG. 13, in operation S100, an electronic element layer 200 is formed above a substrate 100.

The forming of the electronic element layer 200 includes forming a plurality of switching TFTs and a plurality of driving TFTs above the substrate 100.

The forming of the switching TFTs and the driving TFTs includes stacking and patterning a conductive layer, an insulating layer, and a semiconductor layer.

In operation S110, a first electrode layer 300 is formed above the electronic element layer 200.

The first electrode layer 300 is formed by using sputtering (e.g., ITO, IGZO, or MgO), atomic layer deposition (e.g., IGZO or MgO), E-beam evaporation (e.g., MgO), thermal deposition (e.g., WO₃), or the like.

In operation S120, an organic emission layer 400 is formed above the first electrode layer 300.

The forming of the organic emission layer 400 includes forming a hole injection layer, an emission layer, and an electron transport layer.

In operation S130, a first outer layer 305 is formed above the organic emission layer 400.

The first outer layer 505 serves to adjust an FWHM value rather than transmit different colors according to a thickness thereof.

The first outer layer 505 does not have a specific thickness range according to RGB, and the thickness of the first outer layer 505 is determined in a range of 1 nm to 150 nm according to a desired FWHM value.

The first outer layer 505 includes, in addition to WO₃, one or more materials selected from aluminum oxide, aluminum nitride, silicon oxide (SiO₂), silicon nitride, silicon oxynitride, magnesium oxide (MgO), magnesium fluoride, titanium oxide, titanium nitride, hafnium oxide, hafnium nitride, zirconium oxide, and zirconium nitride, such as Al₂O₃, ZnO, ZrO₂, TiO₂, MgO, ZnS, Y₂O₃, HfO₂, SiO₂, SiNₓ and AlN.

The thickness of the first outer layer 505 changes according to the thickness of the intermediate layer and changes according to a refractive index of a material used therein.

When these materials are used, the first outer layer 505 has conductivity when a difference of work functions between the first outer layer 505 and the first metal film 510 is in a range of 0 eV and 2 eV.

In a case where the material of the first outer layer 505 adjacent to the first metal film 510 is a material that does not greatly exhibit conductivity just like the dielectric presented above, if a dielectric having a work function similar to the work function of the first metal film 510 is used (for example, if a difference of work functions is in a range of 0 eV to 2 eV), a difference of work functions when the first metal film 510 contacts the first outer layer 505 is not great. Thus, electrons easily move from the metal to the dielectric and from the dielectric to the metal, and the first outer layer 505 has conductivity accordingly.

In addition, the first outer layer 505 may include TCO such as ITO, IGZO, or IZO.

Furthermore, the first outer layer 505 may include a conductive organic compound such as NPB, Alq3, TPBi, or PEDOT:PSS.

The first outer layer 505 is formed by using sputtering (e.g., ITO, IGZO, or MgO), atomic layer deposition (e.g., IGZO or MgO), E-beam evaporation (e.g., MgO), thermal deposition (e.g., WO₃), or the like.

Then, the first metal film 510 may be stacked above the first outer layer 505 and may include a metal having excellent flexibility and conductivity, such as Ag, Al, Au, Cr, Ni, Pt, Ca, Ta, Cu, and Mo, or any alloy thereof. A thickness of the first metal film 510 may be in a range of 7 nm to 50 nm.

The first metal film 510 may be formed by using thermal deposition (e.g., Ag or Al), sputtering (e.g., Al), E-beam evaporation (e.g., Al), or the like.

In operation S150, an intermediate layer 520 is formed above the first metal film 510.

The intermediate layer 520 is formed by using sputtering (e.g., ITO, IGZO, or MgO), atomic layer deposition (e.g., IGZO or MgO), E-beam evaporation (e.g., MgO), thermal deposition (e.g., WO₃), or the like.

The intermediate layer 520 transmits different colors according to the thickness thereof. In a case where the material of the intermediate layer 520 is WO₃, when the intermediate layer 520 has a thickness greater than 105 nm and equal to or less than 130 nm, the intermediate layer 520 transmits a red-based color best, and thus, the intermediate layer 520 is used as a red color filter electrode layer. When the intermediate layer 520 has a thickness greater than 68 nm and equal to or less than 100 nm, the intermediate layer 520 transmits a green-based color best, and thus, the intermediate layer 520 is used as a green color filter electrode layer 520b. When the intermediate layer 520 has a thickness greater than 40 nm and equal to or less than 65 nm, the intermediate layer 520 transmits a blue-based color best, and thus, the intermediate layer 520 is used as a blue color filter electrode layer 520c.

The intermediate layer 520 is stacked above the first metal film 510 and includes, in addition to WO₃, one or more materials selected from aluminum oxide, aluminum nitride, silicon oxide (SiO₂), silicon nitride, silicon oxynitride, magnesium oxide (MgO), magnesium fluoride, titanium oxide, titanium nitride, hafnium oxide, hafnium nitride, zirconium oxide, and zirconium nitride, such as Al₂O₃, ZnO, ZrO₂, TiO₂, MgO, ZnS, Y₂O₃, HfO₂, SiO₂, SiNₓ, and AlN.

When these materials are used, the intermediate layer 520 has conductivity when a difference of work functions between the first metal film 510 and the second metal film 530 is in a range of 0 eV and 1 eV.

In a case where the material of the intermediate layer 520 inserted between the first metal film 510 and the second metal film 530 is a material that does not greatly exhibit conductivity just like the dielectric presented above, if a dielectric having a work function similar to the work functions of the first metal film 510 and the second metal film 530 is used (for example, if a difference of work functions is in a range of 0 eV and 2 eV), a difference of work functions when the first metal film 510 and the second metal film 530 contact the intermediate layer 520 is not great. Thus, electrons easily move from the metal to the dielectric and from the dielectric to the metal, and the intermediate layer 520 has conductivity accordingly.

In addition, the intermediate layer 520 may include TCO such as ITO, IGZO, or IZO.

Furthermore, the intermediate layer 520 may include a conductive organic compound such as NPB, Alq3, TPBi, or PEDOT:PSS.

In a case where the refractive index is in a range of 1 to 3, the thickness of the intermediate layer 520 is in a range of 1 nm to 230 nm when the intermediate layer 520 is used as a blue color filter electrode layer, the thickness of the intermediate layer 520 is in a range of 30 nm to 270 nm when the intermediate layer 520 is used as a green color filter electrode layer, and the thickness of the intermediate layer 520 is in a range of 40 nm to 320 nm when the intermediate layer 520 is used as a red color filter electrode layer.

The thickness of the intermediate layer 520 is changed according to the refractive index and is determined within the range presented above for each color.

Also, when the first outer layer 505 and the second outer layer 540 are absent, the intermediate layer 520 is within the range described above with reference to FIG. 2B.

In operation S160, the second metal film 530 may be stacked above the intermediate layer 520 and may include a metal having excellent flexibility and conductivity, such as Ag, Al, Au, Cr, Ni, Pt, Ca, Ta, Cu, and Mo, or any alloy thereof.

The second metal film 530 may be formed by using thermal deposition (e.g., Ag or Al), sputtering (e.g., Al), E-beam evaporation (e.g., Al), or the like.

In operation S170, a second outer layer 540 is formed above the second metal film 530.

The second outer layer 540 is formed by using sputtering (e.g., ITO, IGZO, or MgO), atomic layer deposition (e.g., IGZO or MgO), E-beam evaporation (e.g., MgO), thermal deposition (e.g., WO₃), or the like.

The second outer layer 540 serves to adjust an FWHM value rather than transmit different colors according to a thickness thereof.

The second outer layer 540 does not have a specific thickness range according to RGB, and the thickness of the second outer layer 540 is determined in a range of 1 nm to 150 nm according to a desired FWHM value.

The second outer layer 540 is stacked above the second metal film 530 and includes, in addition to WO₃, one or more materials selected from aluminum oxide, aluminum nitride, silicon oxide (SiO₂), silicon nitride, silicon oxynitride, magnesium oxide (MgO), magnesium fluoride, titanium oxide, titanium nitride, hafnium oxide, hafnium nitride, zirconium oxide, and zirconium nitride, such as Al₂O₃, ZnO, ZrO₂, TiO₂, MgO, ZnS, Y₂O₃, HfO₂, SiO₂, SiNₓ, and AlN.

When these materials are used, the second outer layer 540 has conductivity when a difference of work functions between the second outer layer 540 and the second metal film 530 is in a range of 0 eV and 2 eV.

In a case where the material of the second outer layer 540 adjacent to the second metal film 530 is a material that does not greatly exhibit conductivity just like the dielectric presented above, if a dielectric having a work function similar to the work function of the second metal film 530 is used (for example, if a difference of work functions is in a range of 0 eV to 2 eV), a difference of work functions when the second metal film 530 contacts the second outer layer 540 is not great. Thus, electrons easily move from the metal to the dielectric and from the dielectric to the metal, and the second outer layer 540 has conductivity accordingly.

In addition, the second outer layer 540 may include TCO such as ITO, IGZO, or IZO.

Furthermore, the second outer layer 540 may include a conductive organic compound such as NPB, Alq3, TPBi, or PEDOT:PSS.

The thickness of the second outer layer 540 changes according to the thickness of the intermediate layer 520 and changes according to a refractive index of a material used therein.

The color filter electrode layer having the above-described structure may transmit different colors according to a change in the thicknesses of the first outer layer 505, the intermediate layer 520, and the second outer layer 540. Since the first outer layer 505, the intermediate layer 520, and the second outer layer 540 have conductivity, the color filter electrode layer has conductivity as a whole and thus may be used as a line or an electrode.

FIG. 14 is a flowchart of a method of manufacturing an OLED device integrated with a color filter electrode, according to a second embodiment of the present invention.

Referring to FIG. 14, the method of manufacturing the OLED device integrated with the color filter electrode, according to the second embodiment, differs from the method of manufacturing the OLED device integrated with the color filter electrode, according to the first embodiment, in terms of the stacked order. Specifically, the method of manufacturing the OLED device integrated with the color filter electrode, according to the second embodiment, includes forming an electronic element layer above a substrate in operation S200, forming a second outer layer above the electronic element layer in operation S210, forming a second metal film above the second outer layer in operation S200, forming an intermediate layer above the second metal film in operation S230, forming a first metal film above the intermediate layer in operation S240, forming a first outer layer above the first metal film in operation S250, forming an organic emission layer above the first outer layer in operation S260, and forming a first electrode layer above the organic emission layer in operation S270.

Consequently, in the OLED device, the substrate 100, the electronic element layer 200, the color filter electrode layer 500, the organic emission layer 400, and the first electrode layer 300 are stacked in this order. Thus, the OLED device is a bottom-emission type OLED device in which an image is realized toward the substrate 100

In the case of such a bottom-emission type OLED device, the substrate 100 needs to be made of a transparent material.

Structures and features other than those described above are substantially identical to those of the first embodiment, and detailed descriptions thereof will be omitted.

According to the embodiments of the present invention, it is possible to reduce the manufacturing process and simplify the manufacturing process, thereby reducing the manufacturing cost.

In particular, the OLED device includes the color filter electrode layer in which the color filter and the electrode are integrated, and a thermal deposition process used to manufacture the OLED is employed in the method of manufacturing the OLED device. Thus, the color filter electrode layer is just subsequently manufactured at the same time as the manufacturing of the OLED device, without additional processes.

In this manner, the finished device may be manufactured at once without using an existing color filter manufacturing process such as an attachment process, a photolithography process, or the like.

Although preferred embodiments of the present invention have been described for illustrative purposes, those skilled in the art will appreciate that various modifications, additions and substitutions are possible, without departing from the scope and spirit of the invention as disclosed in the accompanying claims.

Therefore, the embodiments of the present invention are disclosed only for illustrative purposes and should not be construed as limiting the present invention.

### Description of Reference Numerals

100: substrate
200: electronic element layer
300: first electrode layer
400: organic emission layer
500: color filter electrode layer
505: first outer layer
510: first metal film
520: intermediate layer
530: second metal film
540: second outer layer

What is claimed is:

1. An organic light emitting diode (OLED) device integrated with a color filter electrode, the OLED device comprising:
a first electrode layer configured to function as an anode electrode to provide holes;
an organic emission layer disposed above the first electrode layer and configured to cause a reaction between the holes and electrons to generate light; and
a color filter electrode layer disposed above the first electrode layer and the organic emission layer and configured to selectively transmit a color in each region, function as a cathode electrode due to conductivity thereof, and provide the electrons to the organic emission layer.

2. The OLED device of claim 1, further comprising an electronic element layer disposed below the first electrode layer and configured to receive a driving signal from an external driver and control the first electrode layer.

3. The OLED device of claim 1, wherein the color filter electrode layer comprises:
a first metal film disposed above the organic emission layer;
an intermediate layer disposed above the first metal film and having conductivity; and
a second metal film disposed above the intermediate layer.

4. The OLED device of claim 3, further comprising a first outer layer disposed between the first metal film and the organic emission layer and having conductivity.

5. The OLED device of claim 4, wherein, when a refractive index of the intermediate layer is in a range of 1.0 to 3.0, the intermediate layer comprises:
a blue color filter electrode layer having a thickness of 1 nm to 230 nm;
a green color filter electrode layer having a thickness of 30 nm to 270 nm; and
a red color filter electrode layer having a thickness of 40 nm to 320 nm.

6. The OLED device of claim 3, further comprising a second outer layer disposed above the second metal film and having conductivity.

7. An organic light emitting diode (OLED) device integrated with a color filter electrode, the OLED device comprising:
a color filter electrode layer configured to selectively transmit a color in each region and function as a cathode electrode to provide electrons;
an organic emission layer disposed above the color filter electrode layer and configured to cause a reaction between the electrons and holes to generate light; and
a first electrode layer disposed above the organic emission layer and configured to function as an anode electrode to provide the holes.

8. The OLED device of claim 7, further comprising an electronic element layer disposed below the color filter electrode layer and configured to receive a driving signal from an external driver and control the color filter electrode layer.

9. The OLED device of claim 7, wherein the color filter electrode layer comprises:
a first metal film disposed below the organic emission layer;
an intermediate layer disposed below the first metal film and having conductivity; and
a second metal film disposed below the intermediate layer.

10. The OLED device of claim 3, wherein the intermediate layer comprises one or more materials selected from aluminum oxide, aluminum nitride, tungsten oxide (WO₃), silicon oxide (SiO₂), silicon nitride, silicon oxynitride, magnesium oxide (MgO), magnesium fluoride, titanium oxide, titanium nitride, hafnium oxide, hafnium nitride, zirconium oxide, and zirconium nitride, and
a difference of work functions between the intermediate layer and the first and second metal films is in a range of 0 eV to 2 eV, so that when power is supplied between the first metal film and the second metal film, electrons move from the first metal film and the second metal film to the intermediate layer and move from the intermediate layer to the first metal film and the second metal film, whereby the intermediate layer has conductivity.

11. The OLED device of claim 3, wherein the intermediate layer comprises transparent conductive oxide (TCO) or a conductive organic compound.

12. The OLED device of claim 3, wherein, when a refractive index of the intermediate layer is in a range of 1.0 to 3.0, the intermediate layer comprises:
a blue color filter electrode layer having a thickness of 15 nm to 170 nm;
a green color filter electrode layer having a thickness of 30 nm to 220 nm; and
a red color filter electrode layer having a thickness of 40 nm to 270 nm.

13. A method of manufacturing an organic light emitting diode (OLED) device integrated with a color filter electrode, the method comprising:
(A) forming a first electrode layer, the first electrode layer being configured to function as an anode electrode to provide holes to an organic emission layer;
(B) forming the organic emission layer above the first electrode layer, the organic emission layer being configured to cause a reaction between the holes and electrons to generate light; and
(C) forming a color filter electrode layer above the first electrode layer and the organic emission layer, the color filter electrode layer being configured to selectively transmit a color in each region and function as a cathode electrode to provide the electrons to the organic emission layer.

14. The method of claim 13, further comprising, before step (A), (D) forming an electronic element layer below the first electrode layer, the electronic element layer being configured to receive a driving signal from an external driver above a substrate.

15. The method of claim 13, wherein (C) comprises:
(C-1) forming a first metal film above the organic emission layer;
(C-2) forming an intermediate layer having conductivity above the first metal film; and
(C-3) forming a second metal film above the intermediate layer.

16. The method of claim 15, further comprising, before step (C-1) of forming the first metal film above the organic emission layer, (C-4) forming a first outer layer having conductivity.

17. The method of claim 15, further comprising (C-5) forming a second outer layer having conductivity above the second metal film.

18. A method of manufacturing an organic light emitting diode (OLED) device integrated with a color filter electrode, the method comprising:
(A) forming a color filter electrode layer, the color filter electrode layer being configured to selectively transmit a color in each region and function as a cathode electrode to provide electrons to an organic emission layer;
(B) forming the organic emission layer above the color filter electrode layer, the organic emission layer being configured to receive holes from a first electrode layer and generate light according to a driving signal of an electronic element layer; and
(C) forming the first electrode layer above the organic emission layer, the first electrode layer being configured to provide the holes to the organic emission layer.

19. The method of claim 18, further comprising, before step (A), (D) forming the electronic element layer below the color filter electrode layer, the electronic element layer being configured to receive a driving signal from an external driver above a substrate.

20. The method of claim 18, wherein (A) comprises:
(A-1) forming a second metal film;
(A-2) forming an intermediate layer having conductivity above the second metal film; and
(A-3) forming a first metal film above the intermediate layer.

21. The method of claim 20, further comprising, before step (A-1) of forming the second metal film above the organic emission layer, (A-4) forming a second outer layer having conductivity.

22. The method of claim 20, further comprising (A-5) forming a first outer layer having conductivity above the first metal film.
